(19) United States
(12) Patent Application Publication
(10) Pub. No.: US 2015/0260768 A1
(43) Pub. Date: Sep. 17, 2015

(54) DETECTION METHOD OF ALGORITHM IN INTEGRATED CIRCUIT

(71) Applicant: Kabushiki Kaisha Toshiba, Minato-ku (JP)

(72) Inventors: Keishi SAKANUSHI, Fujisawa (JP); Katsuhiko IWAI, Yokohama (JP)

(73) Assignee: Kabushiki Kaisha Toshiba, Minato-ku (JP)

(21) Appl. No.: 14/452,661

(22) Filed: Aug. 6, 2014

Related U.S. Application Data
(60) Provisional application No. 61/952,227, filed on Mar. 13, 2014.

(51) Int. Cl. G01R 22/06; G01R 13/02

(52) U.S. Cl. CPC G01R 22/066; G01R 13/0245

(57) ABSTRACT

A detection method of an algorithm in an integrated circuit according to an embodiment includes: acquiring time waveforms of physical information from the integrated circuit in respective operations, by causing the integrated circuit to operate with different input values a plurality of times; calculating intermediate values corresponding to the input values or output values of the integrated circuit, based on a known algorithm; grouping the time waveforms of the physical information based on the intermediate values; and evaluating whether or not the time waveforms of the physical information depend on the intermediate value, and if the time waveforms depend on the intermediate value, determining that the integrated circuit executes the algorithm.

### CROSS-REFERENCE TO RELATED APPLICATIONS

This application is based upon and claims the benefit of priority from U.S Provisional Patent Application 61/952,227, filed on Mar. 13, 2014; the entire contents of which are incorporated herein by reference.

### FIELD

Embodiments described herein relate generally to a detection method of algorithm in an integrated circuit.

### BACKGROUND

In recent years, many algorithms have been invented and patent rights thereof are achieved. However, even if an algorithm which is a patented invention is executed on integrated circuits of third party, in some cases, confirmation of an algorithm is difficult and enforcement of patent rights therefor is difficult. Accordingly, there is a problem in that even if an inventor invents a new algorithm, it is inevitably made confidential as a patent thereof is not filed, and thus the invention is not effectively utilized by public.

### BRIEF DESCRIPTION OF THE DRAWINGS

FIG. 1 is a block diagram illustrating an operation of an algorithm as a detection target in an embodiment;

FIG. 2 is a flow chart illustrating a detection method of the algorithm in an integrated circuit according to the embodiment;

FIG. 3 is a diagram showing an example of a target algorithm;

FIG. 4 is a diagram illustrating a change in an intermediate value; and

FIG. 5A and FIG. 5B are graphs illustrating a relationship between a difference waveform and a detection result, where a horizontal axis is taken as time and a vertical axis is taken as power consumption.

### DETAILED DESCRIPTION

A detection method of an algorithm in an integrated circuit according to an embodiment includes: acquiring time waveforms of physical information from the integrated circuit in respective operations, by causing the integrated circuit to operate with different input values a plurality of times; calculating intermediate values corresponding to the input values or output values of the integrated circuit, based on a known algorithm; grouping the time waveforms of the physical information based on the intermediate values; and evaluating whether or not the time waveforms of the physical information depend on the intermediate value, and if the time waveforms depend on the intermediate value, determining that the integrated circuit executes the algorithm.

Hereinafter, an embodiment of the invention will be described with reference to the drawings.

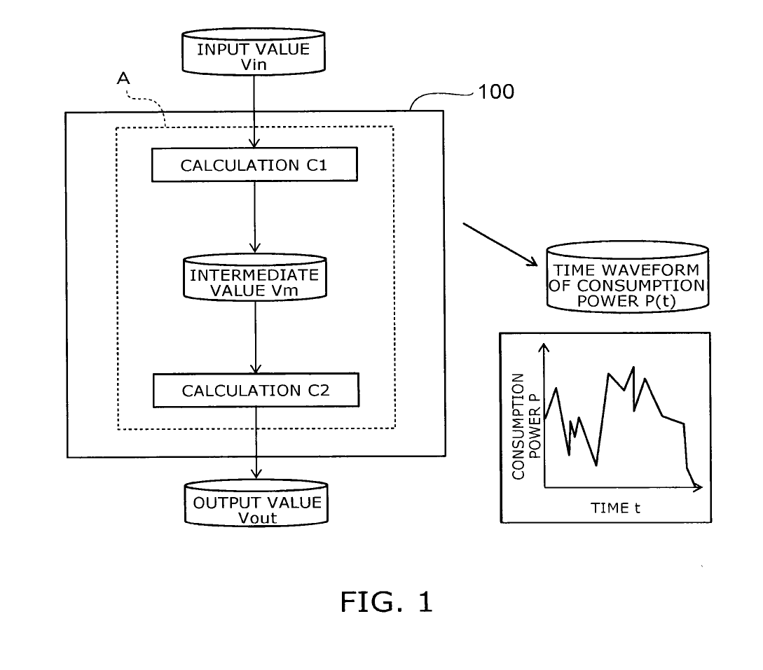

FIG. 1 is a block diagram illustrating an operation of an algorithm as a detection target in the embodiment.

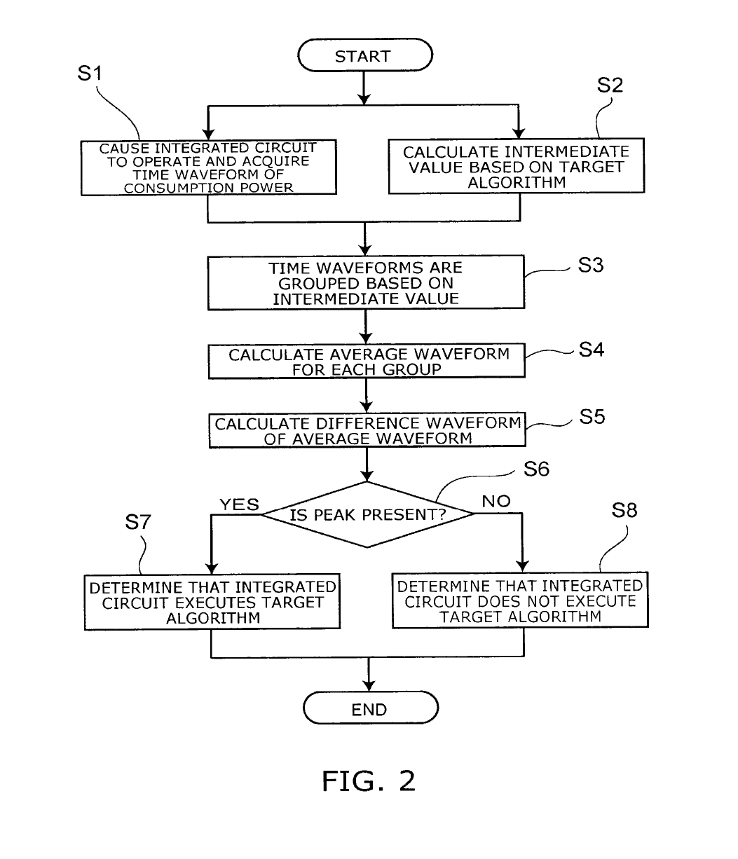

FIG. 2 is a flow chart illustrating a detection method of an algorithm in an integrated circuit according to the embodiment.

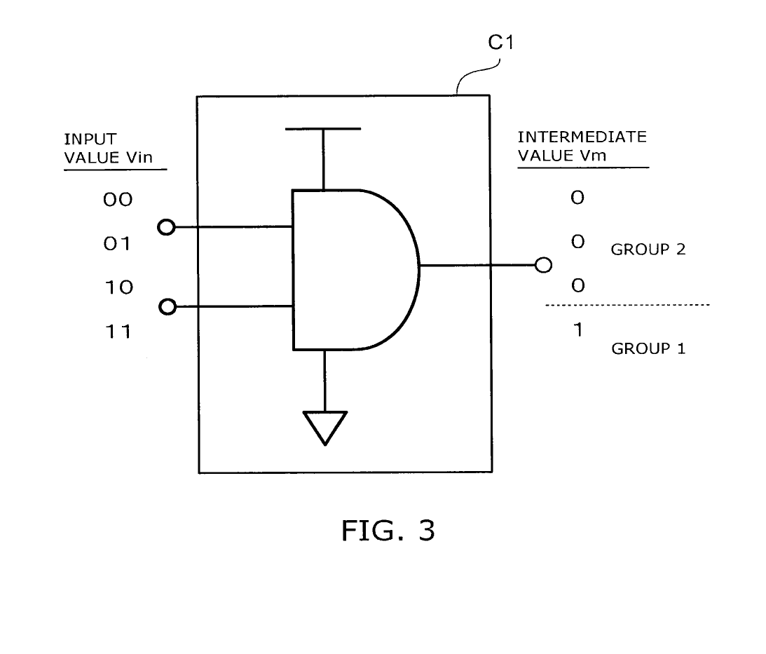

FIG. 3 is a diagram showing an example of a target algorithm.

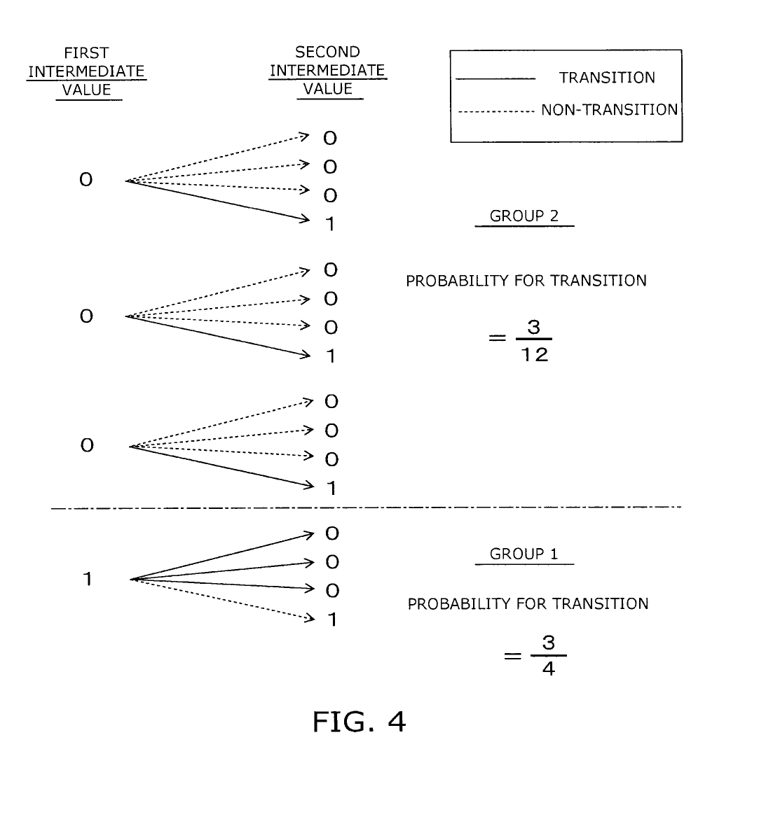

FIG. 4 is a diagram illustrating a change in an intermediate value.

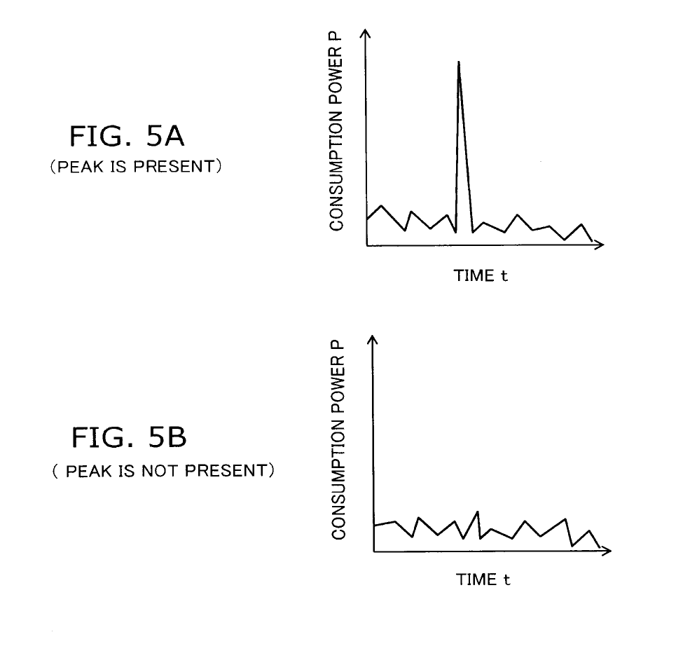

FIG. 5A and FIG. 5B are graphs illustrating a relationship between a difference waveform and a detection result, where a horizontal axis is taken as time and a vertical axis is taken as power consumption.

First, an algorithm to be detected and an integrated circuit will be described.

The embodiment is a method of determining whether or not a certain integrated circuit 100 executes a specific algorithm (hereinafter, referred to as “target algorithm”) A.

The target algorithm A is known to a practitioner of the embodiment. As shown in FIG. 1, calculation C1 and calculation C2 are set in the target algorithm A. An intermediate value Vm is calculated from an input value Vin by the calculation C1, and an output value Vout is calculated from the intermediate value Vm by the calculation C2.

On the other hand, the integrated circuit 100 is produced by another manufacturer, and the circuit configuration and the algorithm thereof are not known to the practitioner. If an input value Vin is input, the integrated circuit 100 outputs an output value Vout. Therefore, the integrated circuit 100 may execute the target algorithm A. If the integrated circuit 100 executes the target algorithm A, the intermediate value Vm corresponding to the input value Vin is supposed to be generated within the integrated circuit 100. However, the intermediate value Vm is not output to the outside of the integrated circuit 100.

Then, a detection method of an algorithm in an integrated circuit according to the embodiment will be described.

First, as shown in FIG. 1 and step S1 of FIG. 2, the integrated circuit 100 receives an input value Vin to operate. Then, a time waveform of physical information of the integrated circuit 100, for example, a time waveform P(t) of power consumption is acquired in each operation. The operation is performed with different input values Vin a plurality of times. The input values Vin are, for example, random. In addition, the time waveform P(t) of power consumption is a measurement value for the time-dependent change in the power consumption. The respective time waveforms P(t) are obtained through two or more processes of calculation of the intermediate value.

On the other hand, as shown in step S2 of FIG. 2, the intermediate values Vm corresponding to the input values Vin are calculated based on the target algorithm A. Since the target algorithm A is known to a practitioner of the embodiment, the calculation is possible.

Next, as shown in step S3, the time waveforms P(t) of the power consumption are grouped based on the intermediate values at a certain time. In a case where respective time waveforms P(t) are obtained through a first calculation process of the intermediate value and a second calculation process of the intermediate value, the time waveforms P(t) are grouped based on the first calculated intermediate value, for example. For example, the time waveforms P(t) are grouped into a group corresponding to one intermediate value and a group corresponding to all intermediate values other than the one intermediate value. In addition, the first calculated intermediate value and the second calculated intermediate value are independent of each other. Hereinafter, this and subsequent processes will be described with reference to a specific example. As shown in FIG. 3, it is assumed that the calculation C1 of the target algorithm A is a logical AND. In this case, the input values Vin are four types: “00”, “01”, “10”, and “11”. Then, the intermediate values Vm corresponding to the input values Vin are respectively “0”, “0”, “0”, and “1”. Then, the time waveforms P(t) of the power consumption resulted from an operation in which the intermediate values Vm become “1”, in other words, an operation when the input value Vin is “11”, are classified into the group 1. On the other hand, the time waveforms P(t) of the power consumption resulted from an operation in which the intermediate values Vm become “0”, in other words, an operation when the input values Vin are “00”, “01”, or “10”, are classified into the group 2.

Next, as shown in step S4, after the time waveforms P(t) are normalized by time, a representative waveform of the time waveforms P(t) of the power consumption of the respective groups, for example, an average waveform is calculated.

As shown in step S5, the difference waveform between the average waveform of the group 1 and the average waveform of the group 2 is calculated. As shown in step S6, whether or not a peak is present in the difference waveform is evaluated.

As shown in FIG. 4, even if the first intermediate value has any value, the second intermediate value is any one of “0”, “0”, “0”, and “1”. Then, if the first intermediate value is assumed as “0”, when the second intermediate value is “1”, the intermediate value transits from “0” to “1”, whereas when the second intermediate value is “0”, the intermediate value does not transit and is maintained at “0”. Therefore, in the group 2, a probability that the intermediate value transits between the first time and the second time is ( 3/12)=(¼). On the other hand, if the first intermediate value is assumed as “1”, when the second intermediate value is “0”, the intermediate value transits from “1” to “0”, whereas when the second intermediate value is “1”, the intermediate value does not transit and is maintained at “1”. Therefore, in the group 1, a probability that the intermediate value transits between the first time and the second time is (¾).

Then, in the integrated circuit 100, when the intermediate value transits, it is necessary to switch a transistor or to rewrite a value of a register, so that power is consumed. Therefore, from a statistical view point, the time waveforms P(t) of the group 1 have greater power consumption as compared to the time waveforms P(t) of the group 2, at a timing when the second intermediate value is calculated. Accordingly, as shown in FIG. 5A, if the difference waveform between the average waveform of the group 1 and the average waveform of the group 2 is calculated, a peak is present at a timing when the second intermediate value is calculated.

In other words, if the peak is present in the difference waveform, it means that a significant difference is present between the time waveform P(t) of the group 1 and the time waveform P (t) of the group 2. If the significant difference is present, it can be determined that the time waveform P(t) of the power consumption depends on the intermediate value Vm. Then, if the time waveform P(t) depends on the intermediate value Vm, the intermediate value Vm is generated in the integrated circuit 100, and thus it represents that the calculations C1 and C2, that is, the target algorithm A is executed.

On the other hand, as shown in FIG. 5B, when the peak is not present in the difference waveform, a significant difference cannot be confirmed between the time waveform P(t) of the group 1 and the time waveform P(t) of the group 2, and thus it cannot be determined that the time waveform P(t) of the power consumption depends on the intermediate value Vm. Therefore, the intermediate value Vm is not generated in the integrated circuit 100, or even if a value corresponding to the intermediate value Vm is generated, the value may be generated by an algorithm other than the target algorithm A. Whatever the case may be, it cannot be confirmed that the target algorithm A is executed in the integrated circuit 100.

Accordingly, if the peak is present in the difference waveform, as shown in step S7 of FIG. 2, it is determined that the integrated circuit 100 executes the target algorithm A. On the other hand, if the peak is not present in the difference waveform, as shown in step 58, it is determined that the integrated circuit 100 does not execute the target algorithm A.

Next, an effect of the embodiment will be described.

According to the embodiment, it is possible to determine whether or not the integrated circuit 100 executes the target algorithm A using a simple method, without damaging the integrated circuit 100.

Note that, in principle, even if a reverse engineering of the integrated circuit 100 is performed, it is possible to determine whether or not the integrated circuit 100 executes the target algorithm A. The reverse engineering is a method of estimating which algorithm is being executed by opening the package of the integrated circuit 100, analyzing a wiring pattern, and reproducing a circuit diagram. However, since the reverse engineering requires a great amount of cost and time and is a destructive inspection, there is a problem in that re-examination is difficult when the inspection fails. In addition, when the reverse engineering is prohibited by a contract, even if it is confirmed that the target algorithm A is executed, there is a probability of lack of admissibility of evidence.

In contrast, according to the embodiment, a determination as to whether the target algorithm A is executed can be promptly implemented at a low cost. Further, even when the target algorithm A is implemented by software or hardware in the integrated circuit 100, the determination is possible in either case. Further, even when the integrated circuit 100 is formed on a large scale integrated circuit (LSI) chip which is distributed as a single unit, or even when the integrated circuit 100 is mounted on electronic devices such as mobile phones, home appliances such as television receivers and refrigerators, and transportation machinery such as vehicles, the determination can be performed. Further, it is possible to determine the algorithm for a system including the integrated circuit.

Hereinafter, some variations of the embodiment will be illustrated.

Although an example is shown in which the intermediate value Vm is calculated from the input value Vin in a process shown in step S2 of FIG. 2 in the embodiment, without being limited thereto, the intermediate value Vm may be calculated from the output value Vout. This is effective in a case where a reverse calculation of the calculation C2 is easier than the calculation C1, and the calculation of the intermediate value Vm from the output value Vout is simpler than the calculation of the intermediate value Vm from the input value Vin.

Further, in the embodiment, a case is shown in which the target algorithm A is configured with the calculations C1 and C2 and the intermediate value Vm is generated, but it is not limited thereto. The number of calculations included in the target algorithm may not be two, but may be one or three or more. Further, the calculations may not be continuously executed, may branch on its way, may be repeated, and parallel calculations may be performed.

Further, although an example is shown in which power consumption is used as the physical information in the embodiment, without being limited thereto, the physical information includes all information that is output along with the operation of the integrated circuit. For example, when the intermediate value transits between “0” and “1”, currents flow to a resistor and the like, and thus electromagnetic waves are radiated. Accordingly, even if the electromagnetic waves are measured as the physical information, it is possible to detect transition of the intermediate value. In addition, since it is possible to specify which part of the integrated circuit operates by measuring the electromagnetic waves, it is possible to more accurately estimate the operation of the integrated circuit. Further, heat radiated from the integrated circuit may be used as the physical information. Furthermore, when the integrated circuit is provided within a case including a cooling fan such as a personal computer use of an operating noise of the cooling fan is considered.

Furthermore, although an example is shown in which the average waveform is used as the representative waveform of the time waveforms belonging to the respective groups in the embodiment, without being limited thereto, the representative waveform may be determined by a statistical method other than an averaging method.

Furthermore, although an example is shown in which the time waveform is classified into the group 1 and the group 2 as a method of evaluating whether or not the time waveform of power consumption depends on the intermediate value in the embodiment, it is determined whether or not the significant difference is present between the time waveforms belonging to the group 1 and the time waveforms belonging to the group 2; and if the significant difference is present, it is determined that the time waveform depends on the intermediate value, but the method is not limited thereto. For example, the time waveforms are classified into three or more groups according to the intermediate values, a correlation between the time waveforms and the intermediate values is evaluated by a correlation analysis, when the correlation is observed, it may be determined that the time waveform of the power consumption depends on the intermediate value.

According to the embodiments described above, it is possible to realize a simple detection method of an algorithm in an integrated circuit at a low cost.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A detection method of an algorithm in an integrated circuit, comprising:
acquiring time waveforms of physical information from the integrated circuit in respective operations, by causing the integrated circuit to operate with different input values a plurality of times;
calculating intermediate values corresponding to the input values or output values of the integrated circuit, based on a known algorithm;
grouping the time waveforms of the physical information based on the intermediate values; and
evaluating whether or not the time waveforms of the physical information depend on the intermediate value, and if the time waveforms depend on the intermediate value, determining that the integrated circuit executes the algorithm.

2. The method according to claim 1, wherein
the grouping includes classifying the time waveforms of the physical information into a first group corresponding to one intermediate value and a second group corresponding to all intermediate values other than the one intermediate value,
the evaluating and determining includes determining whether or not a significant difference is present between the time waveforms belonging to the first group and the time waveforms belonging to the second group, and
if the significant difference is present, it is determined that the time waveforms of the physical information depend on the intermediate values.

3. The method according to claim 2, wherein
the determining whether or not a significant difference is present includes:
calculating a representative waveform of a plurality of the time waveforms belonging to the first group;
calculating a representative waveform of a plurality of the time waveforms belonging to the second group;
calculating a difference waveform between the representative waveform of the first group and the representative waveform of the second group; and
determining whether or not a peak is present in the difference waveform, and
if the peak is present, it is determined that the significant difference is present.

4. The method according to claim 3,
wherein the representative waveform is an average waveform of the plurality of time waveforms.

5. The method according to claim 1,
wherein the physical information is power consumption of the integrated circuit.

6. The method according to claim 1,
wherein the physical information is electromagnetic waves radiated from the integrated circuit.
